(19) United States
(12) Patent Application Publication
(10) Pub. No.: US 2013/0155634 A1
(43) Pub. Date: Jun. 20, 2013

(54) FIXING MEANS FOR INSTALLING A PLURALITY OF OUTPUT CABLES ONTO A CIRCUIT BOARD AND METHOD THEREOF

(71) Applicants: Shengyao Jiang, Shanghai (CN); Lunzi Jing, Shanghai (CN)

(72) Inventors: Shengyao Jiang, Shanghai (CN); Lunzi Jing, Shanghai (CN)

(73) Assignee: DELTA ELECTRONICS (SHANGHAI) CO., LTD, Shanghai (CN)

(21) Appl. No.: 13/544,621

(22) Filed: Jul. 9, 2012

(30) Foreign Application Priority Data
Dec. 16, 2011 (CN) 201110425390.3

(51) Int. Cl. H05K 7/02; H01R 9/00

(52) U.S. Cl. 361/752; 29/842

(57) ABSTRACT

The present invention discloses a fixing means for installing a plurality of output cables onto a circuit board and a method thereof. The method comprises steps of providing a fixing means that includes a fixing housing and interposing terminals, wherein the fixing housing is provided with inserting through holes which are located to correspond to output cable receiving holes on the circuit board, and respectively fixing the output cable inserting end(s) of the output cable(s) to be inserted into one of the output cable receiving holes together with one interposing terminal and forming electric connection; inserting each of the interposing terminals connected with the output cables into the corresponding inserting through hole in the fixing housing and fixing each of the interposing terminals in place; and installing the fixing means onto the circuit board, wherein each interposing terminal is inserted into the corresponding output cable receiving hole.

### CROSS REFERENCE TO RELATED APPLICATIONS

This application claims priority to the Chinese patent application No. 201110425390.3, filed on Dec. 16, 2011, which is incorporated herein by reference in its entirety.

### FIELD OF THE INVENTION

The present invention relates to a fixing means for installing a plurality of output cables and a method thereof, and more particularly, to a fixing means for installing a plurality of output cables onto a circuit board and a method thereof.

### BACKGROUND OF THE INVENTION

In the electronic industry, it is common to connect various output cables to a circuit board. Such output cables are generally connectors for transferring voltage, current, signal and so forth from an electrical product (such as a power supply) to outside. FIG. 1 is a sectional view showing an assembly configuration between a plurality of output cables and a circuit board achieved by the method of installing the output cables in the prior art. In detail, the method of installing a plurality of output cables in the prior art includes the steps of: inserting the plurality of output cables 6 respectively into corresponding output cable receiving holes in a circuit board 3 directly; furnace welding the whole circuit board 3 after all the output cables 6 have been interposed into the corresponding holes on the circuit board according to design requirements, such that the output cables 6 are fixed on and electrically connected with the circuit board 3 by soldering tin 7 on the side opposite to the interposed side of the circuit board.

However, the conventional assembly method has some drawbacks below:

1) it needs to independently and respectively interpose the output cables for considerable times, so that assembling the output cables onto the circuit board is labor consuming;

2) for avoiding short circuit between different polarities, the ends of the output cables should be sleeved with a protective component such as a thermal shrink tube, which would consume more labor and materials;

3) in the event that the protection does not meet the operating requirements, it is possible to cause a risk of burning out the equipment;

4) due to the considerable times and complexity for interposing the plurality of output cables on the circuit board, it is difficult to implement an automatic installation.

5) during the transportation of the output cables, the terminal hooks are easy to deform, which might cause the output cables interposed on the circuit board to fall out when the circuit board is furnace welded.

Therefore, it is necessary to develop a novel fixing means for installing a plurality of output cables onto a circuit board and a method thereof so as to overcome the foregoing defects presented in the conventional assembly method.

### BRIEF SUMMARY OF THE INVENTION

In order to overcome one or more defects in the prior art, one object of the present application, in part, is to provide a fixing means for quickly installing a plurality of output cables in a firmly fix manner and a method thereof, so as to reduce the process of manually interposing the plurality of output cables onto the circuit board and easily implement.

In one aspect, the present invention provides a method for installing a plurality of output cables onto a circuit board, comprising steps of:

Providing (or supplied with) a fixing means that includes a fixing housing and interposing terminals, wherein the fixing housing is provided with a plurality of inserting through holes, and the inserting through holes are alignable with (located to correspond to) output cable receiving holes on the circuit board respectively;

providing the output cables, and fixing an output cable inserting end of at least one output cable, which will be inserted into one of the output cable receiving holes on the circuit board, together with one of the interposing terminals so as to form an electric connection therebetween;

inserting each of the interposing terminals connected with the output cables into the corresponding inserting through hole in the fixing housing and fixing each of the interposing terminals in place; and

installing the fixing means onto the circuit board, wherein each of the interposing terminals is inserted into the corresponding output cable receiving hole on the circuit board.

In some embodiments, the method may further comprise a step of: furnace welding the whole circuit board after each of the interposing terminals is inserted into the corresponding output cable receiving hole on the circuit board, so that the output cables can be fixed onto the circuit board in a manner of electrical connection.

In some other embodiments of the method, the interposing terminal may comprise a fixing portion for fixing the output cable inserting end(s) together with the interposing terminal in a manner of electrical connection, a protruding portion for protruding out of the fixing housing, and an intermediate portion between the fixing portion and the protruding portion.

In further some embodiments of the method, the interposing terminal may be fixed to the fixing housing via the intermediate portion thereof.

In further some other embodiments of the method, the intermediate portion of the interposing terminal may be provided with a locking mechanism for locking with a corresponding locking recess in the fixing housing so as to be positioned in place.

In still some embodiments of the method, the intermediate portion of the interposing terminal may be fixed into the corresponding inserting through hole in the fixing housing by means of interference fit.

In still some other embodiments of the method, the protruding portion of the interposing terminal may be provided with a locking mechanism for locking with the corresponding output cable receiving hole on the circuit board so that the interposing terminal may be fixed onto the circuit board.

In still some other embodiments of the method, in the step of installing the fixing means onto the circuit board, one or more fixing parts may be provided to fix the fixing means onto the circuit board.

In still some other embodiments of the method, the fixing part may be a fixing clip provided on a surface of the fixing housing facing the circuit board, and at least one fixing hole is provided at a corresponding position on the circuit board, so that the fixing means and the circuit board can be fixed together by the locking between the fixing clip and the fixing hole.

In still some other embodiments of the method, the fixing part may be a screwed connector, by which the fixing means can be fixed onto the circuit board.

In another aspect, the present invention further provides a fixing means for installing a plurality of output cables onto a circuit board, comprising:

a fixing housing provided with a plurality of inserting through holes, which are alignable with output cable receiving holes on the circuit board; and

interposing terminals, each of which is fixed together with output cable inserting end(s) of the output cable(s) to form an electric connection therebetween, then inserted into the corresponding inserting through hole in the fixing housing, and protruded out of the fixing housing;

wherein one end of each interposing terminal to be protruded out of the fixing housing may be used to interpose into the corresponding output cable receiving hole on the circuit board.

In some embodiments of the fixing means, the interposing terminal may comprise a fixing portion for fixing the output cable inserting end(s) together with the interposing terminal in a manner of electrical connection, a protruding portion for protruding out of the fixing housing, and an intermediate portion between the fixing portion and the protruding portion.

In some other embodiments of the fixing means, the interposing terminal may be fixed to the fixing housing via the intermediate portion.

In further some embodiments of the fixing means, the intermediate portion of the interposing terminal may be provided with a locking mechanism for locking with a corresponding locking recess in the fixing housing so as to be positioned in place.

In further some other embodiments of the fixing means, the intermediate portion of the interposing terminal may be fixed into the corresponding inserting through hole in the fixing housing by means of interference fit.

In still some embodiments of fixing means, the protruding portion of the interposing terminal may be provided with a locking mechanism for locking with the corresponding output cable receiving hole on the circuit board so that the interposing terminal can be fixed onto the circuit board.

In still some other embodiments of fixing means, the fixing means may be also provided with at least one fixing part, by which the fixing means can be fixed onto the circuit board.

In still some other embodiments of fixing means, the fixing part may be a fixing clip provided on a surface of the fixing housing facing the circuit board, and at least one fixing hole is provided at a corresponding position on the circuit board, so that the fixing means and the circuit board are fixed together by the locking between the fixing clip and the fixing hole.

In still some other embodiments of fixing means, the fixing part may be a screwed connector, by which the fixing means is fixed onto the circuit board.

By applying the conception of the present invention, the labor and material consume can be reduced greatly, the automatic assembling and processing of a plurality of output cables can be achieved, and short circuit incurred between the output cables with different polarities can be avoided effectively.

### BRIEF DESCRIPTION OF THE DRAWINGS

The accompanying drawings, which are included to provide further understanding of the disclosure and are incorporated in and constitute a part of this application, illustrate embodiment(s) of the disclosure and together with the description serve to explain the principle of the disclosure.

The accompanying drawings are not intended to be drawn to scale. In the drawings, each identical or nearly identical component that is illustrated in various figures is represented by a like numeral. For purposes of clarity, not every component may be labeled in every drawing.

In the drawings:

FIG. 1 is a schematic sectional view showing an assembly configuration between a plurality of output cables and a circuit board achieved by the conventional method of installing the output cables;

FIG. 2 is a schematic sectional view showing an exemplary fixing means for installing a plurality of output cables as well as an exemplary interposing configuration among the fixing means, the output cables and a circuit board according to some aspects of the present invention;

FIG. 3 is a schematic sectional view showing an exemplary fixing housing on which a fixing part for fixedly connecting the fixing housing and the circuit board is provided;

FIG. 4 is a schematic sectional view showing an exemplary fixing housing without any fixing part; and

FIG. 5 is a schematic perspective view showing an exemplary structure of an interposing terminal according to the present invention.

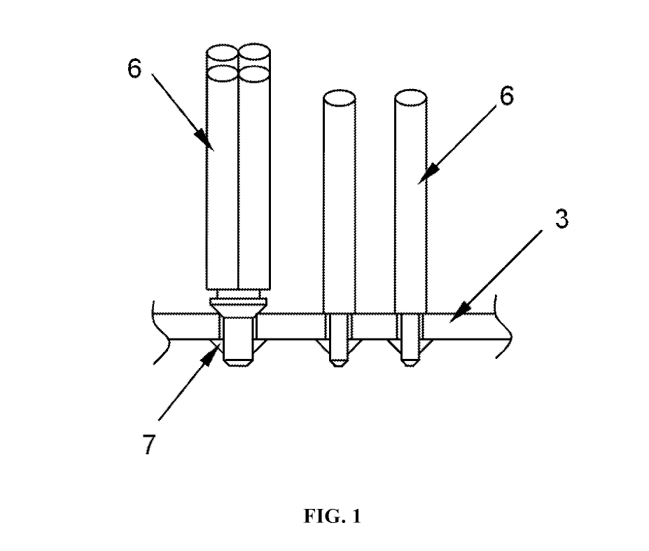

### DETAILED DESCRIPTION OF THE EMBODIMENTS

Reference will now be made in detail to a fixing means for installing a plurality of output cables according to the present invention, examples of which are illustrated in the accompanying drawings.

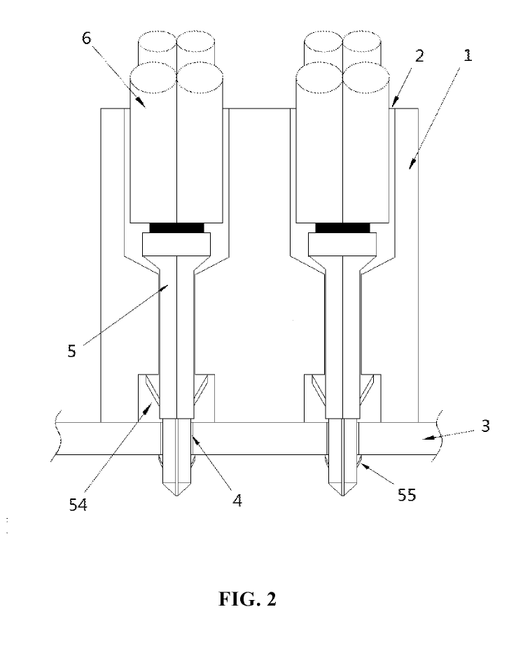

FIG. 2 is a sectional view showing an exemplary fixing means for installing a plurality of output cables as well as an exemplary interposing configuration among the fixing means, the output cables and a circuit board according to the present invention, and schematically showing the interrelated position relation among the fixing means, the output cables 6 and the circuit board 3 after the interposing is completed.

As shown in FIG. 2, the fixing means for installing a plurality of output cables according to the present invention may comprise a fixing housing 1 made of insulating material such as ceramics, plastic (e.g. nylon) and so forth, and provided with a plurality of inserting through holes 2, wherein the positions of the inserting through holes 2 correspond to the positions of the output cable receiving holes 4 on the circuit board 3, respectively; and interposing terminals 5 made of conductive material such as copper and so forth, wherein the inserting ends of the output cables 6 to be inserted into the output cable receiving holes 4 are fixedly connected to the ends of the interposing terminals 5. Based on the actual requirements, it is possible to fixedly connect the inserting end of one output cable 6 to one interposing terminal 5, or fixedly connect the inserting ends of a plurality of output cables 6 to one interposing terminal 5, whereby one or more output cables 6 connected to one interposing terminal 5 are formed.

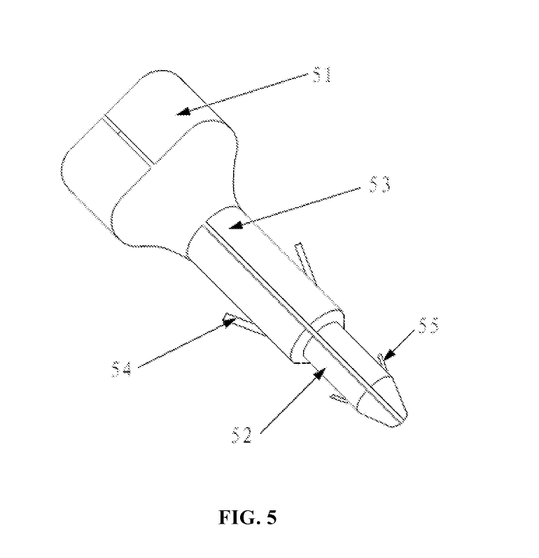

To facilitate for illustration, the main structure of the interposing terminal 5 of the fixing means according to the present invention will be described in brief with reference to FIG. 5. FIG. 5 is a structural schematic view showing an exemplary embodiment of the interposing terminal. The interposing terminal 5 generally has a fixing portion 51 for fixing with the inserting end(s) of the output cable(s) 6 in a manner of electric connection, a protruding portion 52 for protruding out of the fixing housing 1, and an intermediate portion 53 between the fixing portion 51 and the protruding portion 52. Preferably, after the interposing terminal 5 is interposed into the fixing housing 1, both the fixing portion 51 and the intermediate portion 53 are positioned within the fixing housing 1, and only the protruding portion 52 protrudes out of the fixing housing 1. The intermediate portion 53 of the interposing terminal is provided with one locking mechanism 54 and the protruding portion 52 of the interposing terminal is provided with another locking mechanism 55. Both locking mechanisms 54 and 55 are shaped like agnails. The protruding portion 52 and the intermediate portion 53 of the interposing terminal 5 are also provided with longitudinal notches respectively, so that the interposing terminal can be deformed to some extent in the peripheral direction (or in the radial direction) in order to conveniently interpose into the fixing housing 1 and the circuit board 3.

In the fixing means for installing a plurality of output cables according to the present invention, the interposing terminal 5 can be fixed with the inserting end(s) of the output cable 6(s) in various manners.

For instance, in FIG. 2, each interposing terminal 5 is provided with a pressing portion used as the fixing portion 51, by which the cores exposed from the output cables 6 may be clamped such that the fixed and electric connection between the interposing terminal 5 and the inserting end(s) of the output cable(s) 6 can be achieved. Certainly, the present invention is merely illustrative and is not limited to the examples herein. The inserting end(s) of the output cable(s) 6 can also be fixed together with the fixing portion 51 of the interposing terminal 5 in other manners such as welding, screwing and so on.

In addition, in the fixing means for installing a plurality of output cables according to the present invention, the interposing terminal 5 and the fixing housing 1 can be fixed in various manners.

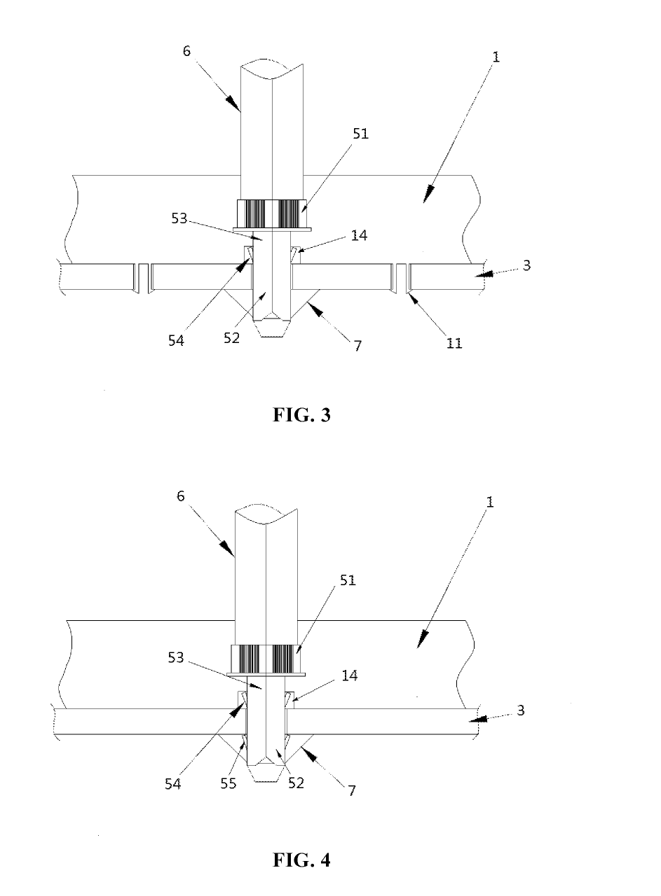

In FIG. 2, FIG. 3 and FIG. 4, for example, the locking mechanism 54 shaped like agnail and provided on the intermediate portion 53 of the interposing terminal 5 is preferably located adjacent to the end of the protruding portion 52. After the interposing terminal 5 goes through the inserting through hole 2 in the fixing housing 1 and the protruding portion 52 protrudes out of the fixing housing 1, the locking mechanism 54 may be cooperated with the corresponding locking recess 14 in the fixing housing 1 to implement the fixed connection between the interposing terminal 5 and the fixing housing 1, so as to prevent the interposing terminal 5 from dropping out of the inserting through hole 2, and, in the meantime, to ensure that the interposing terminal 5 will not be detached from the fixing housing 1 or relatively moved in the fixing housing 1 in the subsequent processing. However, the present invention is not limited to the examples herein. The locking mechanism 54 can be shaped like an inverted cone, or can be a protrusion or tab; or alternatively, no locking mechanism 54 is provided, and the intermediate portion 53 of the interposing terminal 5 can be fixed with the fixing housing 1 directly by means of interference fit.

Hereinafter, the positioning between the fixing means for installing a plurality of output cables according to the present invention and the circuit board 3 will be described. According to the technical concept of the present invention, the fixing means and the circuit board 3 can be fixed with each other by various fixing parts.

FIG. 3 is a schematic sectional view showing that a fixing part is provided on the fixing housing 1 for fixedly connecting the fixing housing to the circuit board 3. In this embodiment, one or more fixing clips 11 used as the fixing part are provided on the surface of the fixing housing 1 facing to the circuit board 3, and a fixing hole is provided at the corresponding position on the circuit board 3. The fixing hole, for example, is a through hole through which the fixing clip 11 can pass, as shown in FIG. 3. However, there is no limitation to the form of the fixing hole. When the fixing housing 1 is installed onto the circuit board 3, the fixing clip 11 may pass through the corresponding fixing hole on the circuit board 3 such that the fixing housing 1 and the circuit board 3 are fixed together in a locking manner. Since the fixing housing 1 is fixed on the circuit board 3 as such, the interposing terminal 5 fixed in the fixing housing 1 can not move relative to the circuit board 3, whereby the fixing means is fixed to the circuit board 3. It can be seen that the fixing clip 11 is designed to not only perform an auxiliary function of fixing the output cables 6 before the whole circuit board is furnace welded, but also perform an additional function of assisting soldering tin 7 to fix the output cables 6 after the furnace welding. It should be noted that there is no limitation to the way by which the fixing housing 1 is fixed together with the circuit board 3. For instance, the interposing terminal 5 for instance can be fixed together with the circuit board 3 by the soldering tin 7 after the furnace welding (see FIG. 3) so as to fix the fixing housing 1 onto the circuit board 3, or a fixing part such as an additional screwed connector can be provided so as to fix the fixing housing 1 onto the circuit board 3.

As further shown in FIG. 4, FIG. 4 is a schematic sectional view showing the fixing housing 1 without any fixing part. In this embodiment, one locking mechanism 54 is provided on the intermediate portion 53 of the interposing terminal 5, another locking mechanism 55 is provided at a predetermined position of the protruding portion 52, and said another locking mechanism 55 can be regarded as a modified example of the above fixing part. Similar to the locking mechanism 54, said another locking mechanism 55 can be shaped like agnail, inverted cone, or can be a protrusion or a tab, etc. In this embodiment, said another locking mechanism 55 can be fixed to the corresponding output cable receiving hole 4 on the circuit board 3 in a locking manner. When the fixing housing 1 is installed onto the circuit board 3, the interposing terminal 5 passes through the output cable receiving hole 4 on the circuit board 3 such that the interposing terminal 5 can be fixed together with the circuit board 3 by means of said another locking mechanism 55 and/or soldering tin 7. Since the interposing terminal 5 has been fixed to the fixing housing 1, the fixing housing 1 can be fixed together with the circuit board 3, whereby the fixing means is fixed onto the circuit board 3. Consequently, a fixed connection is indirectly formed between the fixing housing 1 and the circuit board 3 by said another locking mechanism 55. Said another locking mechanism 55 not only performs an assistant function of fixing the output cables 6 before furnace welding, but also performs an additional fixed function of assisting the soldering tin 7 to fix the output cables 6 after the furnace welding.

Hereinafter, a method of installing a plurality of output cables onto a circuit board according to the present invention will be described in brief:

providing a fixing means, which comprises a fixing housing 1 provided with a plurality of inserting through holes 2 and interposing terminals 5, in which the inserting ends of the output cables 6 to be inserted into the output cable receiving holes 4 are fixed together with the interposing terminals 5 so as to form an electric connection;

subsequently, inserting and fixing the interposing terminals 5 connected with the output cables 6 into the corresponding inserting through holes 2 in the fixing housing 1 in place; and

after that, installing the fixing means onto the circuit board 3 so that the interposing terminals 5 could be directly inserted into the corresponding output cable receiving holes 4 on the circuit board 3 manually or automatically.

The aforementioned steps are illustrating, while different orders of the steps may be practicing as long as the output cables are installed onto a circuit board to form the structures described herein.

As described above, compared with the conventional method of installing a plurality of output cables, the fixing means for installing a plurality of output cables onto a circuit board and the method thereof according to the present invention, in part, have notable advantages below:

1) the labor cost is reduced greatly;

2) the protective materials such as the thermal shrink tube are saved, so that material cost is reduced;

3) the automatic assembling and processing of the plurality of output cables can be conveniently achieved;

4) the short circuit between the plurality of output cables of different polarities can be efficiently prevented; and

5) the reliability of the products is improved, and the invalidation of the product terminal due to extrusion during transportation is avoided.

The foregoing embodiments and advantages are merely exemplary and are not to be construed as limiting the present invention. This description is intended to be illustrative, and not to limit the scope of the claims. Many alternatives, modifications, and variations will be apparent to those skilled in the art. The features, structures, methods, and other characteristics of the exemplary embodiments described herein may be combined in various manners to obtain additional and/or alternative exemplary embodiments.

As the present features may be embodied in several forms without departing from the characteristics thereof, it should also be understood that the above-described embodiments are not limited by any of the details of the foregoing description, unless otherwise specified, but rather should be construed broadly within its scope as defined in the appended claims, and therefore all changes and modifications that fall within the metes and bounds of the claims, or equivalents of such metes and bounds are therefore intended to be embraced by the appended claims.

What is claimed is:

1. A method for installing a plurality of output cables onto a circuit board, comprising steps of:
providing a fixing means that comprises a fixing housing and interposing terminals, wherein the fixing housing is provided with a plurality of inserting through holes, and the inserting through holes are alignable with output cable receiving holes on the circuit board, respectively;
providing the output cables, and fixing an output cable inserting end of at least one output cable, which will be inserted into one of the output cable receiving holes on the circuit board, together with one of the interposing terminals so as to form an electric connection;
inserting each of the interposing terminals connected with the output cables into the corresponding inserting through hole in the fixing housing and fixing each of the interposing terminals in place; and
installing the fixing means onto the circuit board, wherein each of the interposing terminals is inserted into the corresponding output cable receiving hole on the circuit board.

2. The method according to claim 1, further comprising a step of: furnace welding the circuit board after each of the interposing terminals is inserted into the corresponding output cable receiving hole on the circuit board, so that the output cables are fixed onto the circuit board in a manner of electric connection.

3. The method according to claim 1, wherein the interposing terminal comprises:
a fixing portion for fixing the output cable inserting end of at least one output cable together with the interposing terminal in a manner of electric connection;
a protruding portion for protruding out of the fixing housing; and
an intermediate portion between the fixing portion and the protruding portion.

4. The method according to claim 3, wherein the interposing terminal is fixed to the fixing housing via the intermediate portion thereof.

5. The method according to claim 4, wherein the intermediate portion of the interposing terminal is provided with a locking mechanism for locking with a corresponding locking recess in the fixing housing so as to be positioned in place.

6. The method according to claim 4, wherein the intermediate portion of the interposing terminal is fixed into the corresponding inserting through hole in the fixing housing by means of interference fit.

7. The method according to claim 3, wherein the protruding portion of the interposing terminal is provided with a locking mechanism for locking with the corresponding output cable receiving hole on the circuit board so that the interposing terminal can be fixed onto the circuit board.

8. The method according to claim 1, wherein in the step of installing the fixing means onto the circuit board, the fixing means is fixed onto the circuit board by one or more fixing parts.

9. The method according to claim 8, wherein the fixing part is a fixing clip provided on a surface of the fixing housing facing the circuit board, and at least one fixing hole is provided at a corresponding position on the circuit board, so that the fixing means and the circuit board are fixed together by the locking between the fixing clip and the fixing hole.

10. The method according to claim 8, wherein the fixing part is a screwed connector, by which the fixing means is fixed onto the circuit board.

11. A fixing means for installing a plurality of output cables onto a circuit board, comprising:
a fixing housing provided with a plurality of inserting through holes, which are alignable with output cable receiving holes on the circuit board; and
interposing terminals, each of which can be fixed together with an output cable inserting end of at least one output cable to form an electric connection therebetween, then inserted into the corresponding inserting through hole in the fixing housing and protruded out of the fixing housing;
wherein, one end of each interposing terminal to be protruded out of the fixing housing can be interposed into the corresponding output cable receiving hole on the circuit board.

12. The fixing means according to claim 11, wherein the interposing terminal comprises:
a fixing portion for fixing the output cable inserting end(s) together with the interposing terminal in a manner of electric connection;
a protruding portion for protruding out of the fixing housing; and
an intermediate portion between the fixing portion and the protruding portion.

13. The fixing means according to claim 12, wherein the interposing terminal is fixed to the fixing housing via the intermediate portion.

14. The fixing means according to claim 13, wherein the intermediate portion of the interposing terminal is provided with a locking mechanism for locking with a corresponding locking recess in the fixing housing so as to be positioned in place.

15. The fixing means according to claim 13, wherein the intermediate portion of the interposing terminal can be fixed into the corresponding inserting through hole in the fixing housing by means of interference fit.

16. The fixing means according to claim 12, wherein the protruding portion of the interposing terminal is provided with a locking mechanism for locking with the output cable receiving hole on the circuit board so that the interposing terminal can be fixed onto the circuit board.

17. The fixing means according to claim 11, wherein the fixing means is also provided with at least one fixing part, by which the fixing means can be fixed onto the circuit board.

18. The fixing means according to claim 17, wherein the fixing part is a fixing clip provided on a surface of the fixing housing facing the circuit board, and at least one fixing hole is provided at a corresponding position on the circuit board, so that the fixing means and the circuit board are fixed together by the locking between the fixing clip and the fixing hole.

19. The fixing means according to claim 17, wherein the fixing part is a screwed connector, by which the fixing means is fixed onto the circuit board.
